(19) United States
(12) Patent Application Publication
(10) Pub. No.: US 2018/0083440 A1
(43) Pub. Date: Mar. 22, 2018

(54) INTEGRATED CIRCUIT ELECTROSTATIC DISCHARGE PROTECTION WITH DISABLE-ENABLE

(71) Applicant: Globalfoundries Singapore Pte. Ltd., Singapore (SG)

(72) Inventors: Wei Gao, Singapore (SG); Handoko Linewih, Singapore (SG)

(21) Appl. No.: 15/268,703

(22) Filed: Sep. 19, 2016

(51) Int. Cl. H02H 9/04; H01L 27/02; H01L 23/498

(52) U.S. Cl. CPC H02H 9/046; H01L 23/49811; H01L 27/0292; H01L 27/0266

(57) ABSTRACT

Integrated circuits with electrostatic discharge (ESD) protection and methods of providing ESD protection in an integrated circuit are provided, which include an ability to off-chip disable/enable the ESD protection. An ESD Protection Circuit incorporates a disable/enable device coupled to the ESD protection circuit. The disable/enable is addressable from a pin out, e.g., an ESD disable/enable pin of the IC package.

### TECHNICAL FIELD

The technical field generally relates to integrated circuits with electrostatic discharge protection, and in particular, the technical field relates to electrostatic discharge protection circuits and methods of providing electrostatic discharge protection within an integrated circuit that does not interfere with the normal operation of the integrated circuit.

### BACKGROUND

Electrostatic discharge (ESD) has been around since the beginning of time. It is the sudden flow of electricity between two electrically charged objects caused by contact, an electrical short, or dielectric breakdown. However, this natural phenomenon has only become an issue with the widespread use of semi-conductor based integrated circuits and electronics.

All materials (insulators and conductors alike) are sources of ESD. These materials are lumped together in what is known as the triboelectric series, which defines the materials associated with positive or negative charges. Positive charges accumulate predominantly on human skin or animal fur. Negative charges are more common to synthetic materials such as plastics. The amount of electrostatic charge that can accumulate on any item, whether that charge be positive or negative, is dependent on the material and its capacity to store a charge.

The majority of present day integrated circuits (ICs) are implemented by using a plurality of interconnected field effect transistors (FETs), also called metal oxide semiconductor field effect transistors (MOSFETs or MOS transistors). A MOS transistor includes a gate electrode as a control electrode overlying a semiconductor substrate and spaced-apart source and drain regions in the substrate between which a current can flow. A gate dielectric is disposed between the gate electrode and the semiconductor substrate to electrically isolate the gate electrode from the substrate. A control voltage applied to the gate electrode controls the flow of current through a channel in the substrate underlying the gate electrode between the source and drain regions.

An integrated circuit may be subjected to an electrostatic discharge (ESD) event during the manufacturing process, assembly handling and in the ultimate system application. The energy associated with this transient discharge can easily damage the fragile devices present within the integrated circuit (IC).

In the processing and handling of integrated circuits, ESD may originate from any number of sources such as a mechanical chip carrier, a plastic chip storage device, or even human interaction with the process. In each case it is possible that the integrated circuit is subjected to a voltage that is many times greater than its design voltage. The human body, for example, can store a charge equal to 250 picofarads. This correlates into a stored charge that can be as high as 25,000V. For integrated circuits that operate at voltages of less than, for example, 5V (volts), an electrostatic discharge on the order of several thousand volts can be devastating.

External pins or pads form the connection points for the integrated circuit to the outside world and therefore also serve as pathways for ESD events. An ESD event applied to a pad may couple the ESD voltage exceeding several thousand volts to circuitry coupled to the pad. Therefore, the coupling of ESD to the external pins is also of particular concern to the IC package and circuit designer.

In one conventional IC ESD protection scheme, often referred to as a dynamic trigger scheme, special clamp circuits are often used to shunt ESD current between the IC power supply rails and thereby protect internal elements from damage. A type of ESD clamp circuit, known as an active metal oxide semiconductor field effect transistor (MOSFET) clamp circuit, typically consists of three functional elements: an RC detector or trigger circuit, several stages of inverters and a large (total width of multi parallel) MOSFET transistor. The detector circuit is designed to respond to an applied signal rise time of ESD event but remain inactive during normal operation of the IC. The inverter stages are used to amplify the detector circuit output in order to drive the gate terminal of the large MOSFET transistor. The large MOSFET transistor, connected between the two power supply rails, acts as the primary ESD current dissipation device in the clamp circuit. Active MOSFET clamp circuits typically rely on only MOSFET action to shunt ESD current between the rails. Since the peak current in an ESD event may be on the order of amperes, very large MOSFET transistor sizes are required. Generally speaking, these arrangements are limited to ICs of two-rail constructions, e.g., Vdd and Vss rails, wherein all the gates are or should be driven to full Vdd potential.

Another conventional scheme, often referred to as a static trigger scheme, provides a voltage clamp between the IC power rails, e.g., Vdd and Vss. The voltage clamp may utilize Zener or other suitable clamping diode arrangements.

ESD protection must be active during process stages, such as, pre-assembly stages during packaging/shipping/handling/assembling. After assembly, ESD protection is no longer required and is not used. At this point, the ESD protection is considered to be “at standby.” More importantly, ESD protection must not, in standby, interfere with normal operation of the IC.

For dynamic protection, e.g., RC clamp ESD protection circuits, typically an RC time constant is chosen of approximately 1 micro-second (˜=1 μs), which provides assurance that the ESD protection remains active during ESD event duration. However, there remains the possibility of the ESD protection RC clamp circuit mis-triggering during normal operation of the IC causing unwanted interference with the normal performance/operation of the IC. Furthermore, during a fast power on/reset/cycling of the IC, the RC clamp has a possibility of entering oscillation.

Accordingly, it is desirable to provide ESD protection that is active and effective during the process stages, such as, pre-assembly stages during packaging/shipping/handling/assembling, but which is assuredly “off” during normal IC operation so that the ESD protection does not inhibit or interfere with normal operation of the IC.

### BRIEF SUMMARY

Integrated circuits with electrostatic discharge (ESD) protection and methods of providing ESD protection in an integrated circuit are provided, which include an ability to off-chip disable/enable the ESD protection. In an exemplary embodiment, an ESD Protection Circuit incorporates a disable/enable device coupled to the ESD protection circuit. The disable/enable device is addressable from a pin out, e.g., an ESD disable/enable pin of the integrated circuit package.

In one possible embodiment, an ESD Protection Circuit incorporates a disable/enable device coupled to a clamp transistor of the ESD protection circuit. The disable/enable device is addressable from a pin out, e.g., an ESD disable/enable pin.

In another possible embodiment, an ESD Protection Circuit incorporates a disable/enable device coupled to an RC trigger circuit of the ESD protection circuit. The disable/enable device is addressable from a pin out, e.g., an ESD disable/enable pin.

In yet another possible embodiment, an ESD Protection Circuit incorporates a disable/enable device coupled to a buffer circuit of the ESD protection circuit. The disable/enable device is addressable from a pin out, e.g., an ESD disable/enable pin.

An IC may incorporate more than one ESD protection circuit. In such IC structures with more than one ESD protection circuit, each such ESD protection circuit may have an associated disable/enable device. Furthermore, each of the disable/enable devices may be merged together to provide disable/enable of the ESD protection through a single pin out, or each of the disable/enable devices may be individually addressable.

In accordance with further herein described embodiments, provided is a method of disabling/enabling an IC ESD protection circuit. The ESD protection circuit may be disabled/enabled via a signal applied to a pin out of the IC package that is coupled to a disable/enable device internal to the IC and associated with the ESD protection circuit.

Packages for an IC may and typically have several pin outs including at least a first power rail pin (Vdd) and a second power rail pin (Vss). In additional embodiments, the arrangement of the pins on the IC package are such that during handling of the IC package ESD protection is not inadvertently disabled via the disable/enable pin out. Advantageously, the ESD protection disable/enable pin may be located in proximity to the Vss rail pin or Vdd rail pin based upon a low-effective or high-effective disable/enable configuration of the ESD protection disable/enable device.

Advantageously, ESD Protection Circuit structures and methods of providing ESD protection in integrated circuits in accordance with embodiments may be achieved without fabrication process changes, but can be implemented as design methodologies.

### BRIEF DESCRIPTION OF THE DRAWINGS

The present embodiments will hereinafter be described in conjunction with the following drawing figures, wherein like numerals denote like elements, and wherein:

FIG. 1 is a schematic circuit diagram of an integrated circuit with at least one electrostatic discharge protection circuit that includes a disable/enable device in accordance with herein described embodiments;

FIG. 2 is schematic circuit diagram of an integrated circuit with multiple electrostatic discharge protection circuits each including disable/enable devices in accordance with herein described embodiments;

FIG. 3 is a schematic circuit diagram of an alternate arrangement of the circuit depicted in FIG. 2;

FIG. 4 is a schematic circuit diagram of an integrated circuit with at least one electrostatic discharge protection circuit that includes a disable/enable device in accordance with herein described embodiments;

FIG. 5 is schematic circuit diagram of an integrated circuit with multiple electrostatic discharge protection circuits each including disable/enable devices in accordance with herein described embodiments;

FIG. 6 is a schematic circuit diagram of an alternate arrangement of the circuit depicted in FIG. 5;

FIGS. 7a and 7b are graphic depictions of IC package pin layouts in accordance with a herein described embodiment; and

FIGS. 8a and 8b are graphic depictions of IC package pin layouts in accordance with another herein described embodiment.

### DETAILED DESCRIPTION

The following detailed description is merely exemplary in nature and is not intended to limit the various embodiments or the application and uses thereof. Furthermore, there is no intention to be bound by any theory presented in the preceding background or the following detailed description. Embodiments of the present disclosure are generally directed to integrated circuits, and methods for configuring and operating the same. The various structures, elements, tasks and steps described herein may be incorporated into a more comprehensive structure, procedure or process having additional elements, steps or functionality not described in detail herein. In particular, many structures, designs and methods of producing integrated circuits are well-known and so, in the interest of brevity, many conventional aspects of ICs will only be mentioned briefly herein or will be omitted entirely without providing the well-known details.

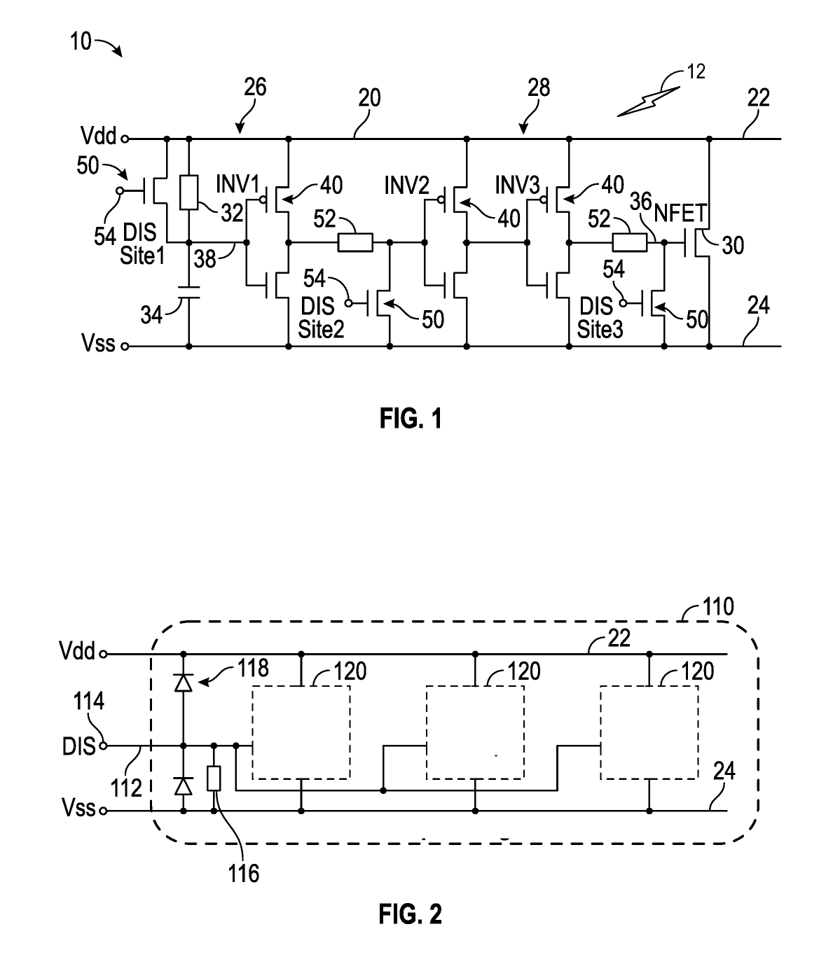

Referring to the exemplary embodiment in FIG. 1, an integrated circuit 10 includes ESD event triggered ESD protection circuit 20. The ESD protection circuit 20 protects the integrated circuit 10 from an ESD event with graphically depicted in FIG. 1 as ESD event 12, referenced between a Vdd power supply rail 22 grounded Vss power supply rail 24. ESD protection circuit 20 includes a trigger circuit 26, a buffer circuit 28 and a N-channel MOSFET transistor 30. The protection circuit 20 is responsive to a positive ESD by activation of the transistor 30 and to a negative ESD passing through the parasitic diode effect of the transistor 30.

The trigger circuit 26 is designed as a resistor-capacitor (RC) transient detector, utilizing a resistive element, shown as resistor 32 and a capacitive element, shown as capacitor 34. It will be appreciated that implementations of ESD protection circuit 20 may use virtually any suitable resistive and capacitive structures to form trigger circuit 26. Furthermore, the ESD protection circuit 20 may be of other formats, provided that the circuit is amendable to a disable/enable implementation.

The buffer circuit 28 drives the gate 36 of the transistor 30 relative to a voltage at node 38 of the trigger circuit 26. As shown, the buffer circuit 28 may be one, but typically more than one inverter, and as illustrated in FIG. 1, in one implementation the buffer circuit 28 incorporates three (3) operatively coupled inverters 40.

In response to a positive ESD event 12 inducing a rapid positive voltage increase on the Vdd rail 22, trigger circuit 26 drives the node 38 to Vdd. The buffer circuit 28, with an input connected to node 38, then attempts to drive the gate 36 of transistor 30 to Vdd, to turn on the transistor 30, i.e., Vg Vdd. Turned on, the transistor 30 becomes an effective, low resistance shunt between Vdd rail 22 and Vss rail 24.

Further shown in FIG. 1, associated with the ESD protection circuit 20 is a disable/enable device 50. The device 50 may be a high-effective switch, e.g., transistor, operatively disposed within the ESD protection circuit 20. The device 50 may be disposed to effectively disrupt or disable one or more of the trigger circuit 26, the buffer circuit 28 or the transistor 30. FIG. 1 depicts the device 50 disposed at sites (1), (2) or (3). It will be appreciated that normally one device 50 is enough, and would in operative embodiments be disposed at any one of sites (1), (2) or (3), and therefore, FIG. 1 efficiently illustrates several possible locations for the device 50 within the ESD protection circuit 20. However, the multiple sites arrangement may be used to ensure that the ESD protection is fully and completely disabled in the particular application.

With continued reference to FIG. 1, placing the device 50 at Site (1) is advantageous. As a high-effective switch, the device 50 effectively disables the trigger circuit 26 by bypassing the resistor 32 and pulling UP/shorting node 38 to Vdd potential, inhibiting activation of the transistor 30 through buffer circuit 28.

FIG. 1 further illustrates the possibility of placing the device 50 at site (2) or (3). At site (2) the device 50 effectively disables the buffer circuit 28 by disabling one of the inverters 40 therein. Likewise, if positioned at site (3), the device 50 effectively disables the transistor 30. With the device 50 placed at either site (2) or site (3), it is required to provide a series resistor (illustrated as resistor 52 in both implementations).

In each of the constructions shown in FIG. 1, the device 50 includes a node (node 54 for each possible implementation). The node 54 couples to a pin out (not depicted) of the IC 10 such that a state of the device 50 may be effected by application of a signal on the associated pin out. In the possible implementation depicted in FIG. 1, the disable device 50 is high-effective. Advantageously, unconnected, such as when the IC is not associated with a printed circuit board (PCB), the disable device 50 is inoperative, and the ESD protection circuit 20 is operative fully to naturally protect the IC 10.

FIG. 2 illustrates an IC 110 that incorporates multiple ESD protection circuits 120, with three (3) depicted coupled between Vdd rail 22 and Vss rail 24. It will be appreciated that the arrangement of FIG. 2 may be further used for different Vdd and Vss rails configurations, i.e. multi domain RC-clamp ESD protection schemes. It should be understood that the IC 110 may include fewer than three or more than three circuits 120. Each of the circuits 120 incorporate a disable/enable device (not depicted). A suitable disable/enable device is the device 50 described in connection with FIG. 1.

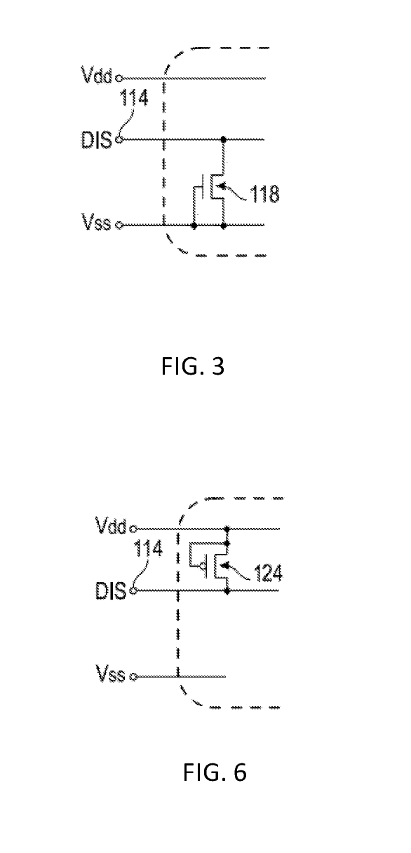

Each of the disable/enable devices of the circuits 120 are coupled to a common ESD disable/enable line 112 that is further coupled to an ESD disable/enable pin out 114 of the IC 110. Each of the disable/enable devices being configured as a high-effective device, a pulling down resistor 116 is provided between line 112 and Vss rail 24. Additionally, as will be appreciated by the skilled person, a protecting pulling up diode pair 118 is provided. In an alternative arrangement depicted in FIG. 3 a gate grounded salicided block NMOS (GGNMOS) transistor 119 is used in place of the diode pair 118 and pulling down resistor 116. In this configuration, each of the ESD circuits 120 may be disabled via application of a signal to the disable/enable pin out 114.

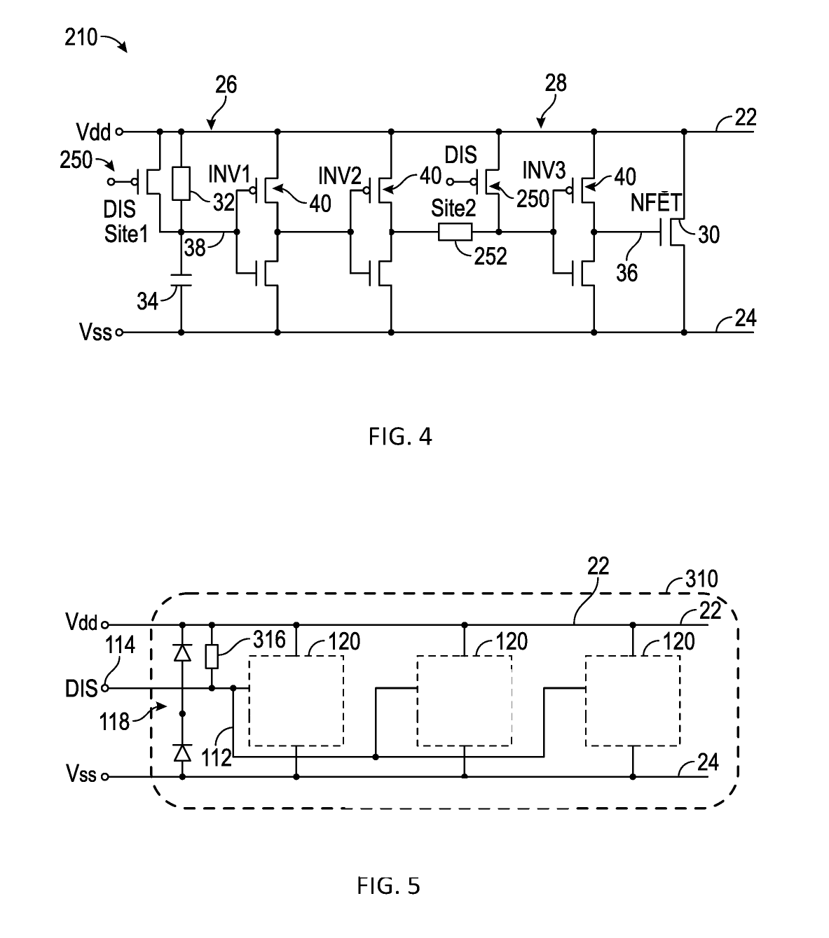

FIGS. 4 and 5 illustrate IC 210 and IC 310, respectively, similar in construction to IC 20 and IC 110, and like reference numerals are used to identify like elements. IC 210 and IC 310 implement ESD circuit disable/enable devices 250, respectively, that are designed as low-effective switches. As low-effective devices, to provide passive ESD protection, the pulling down resistors of IC 10 and IC 110 are replaced with pulling up resistors 316 as shown in FIG. 5. In an alternative arrangement depicted in FIG. 6 a gate pull-up salicided blocked PMOS (GPPMOS) transistor 125 is used in place of the diode pair 118 and pulling up resistor 316.

Several embodiments of ESD protection circuits of ICs that incorporate disable/enable devices are shown and described in connection with FIGS. 1-6. Advantageously, the described embodiments, and modifications thereof, permit one or more ESD protection circuits disposed on the IC to be disabled via a signal potential/bias/voltage applied to an external pin. This arrangement provides the further advantage that absent the signal applied to the external pin, the ESD protection circuit is enabled. Thus, the ESD protection is enabled during normal handling and processing of the IC to final application, and in particular, is enabled and active for pick and place (P&P) type handling of the IC.

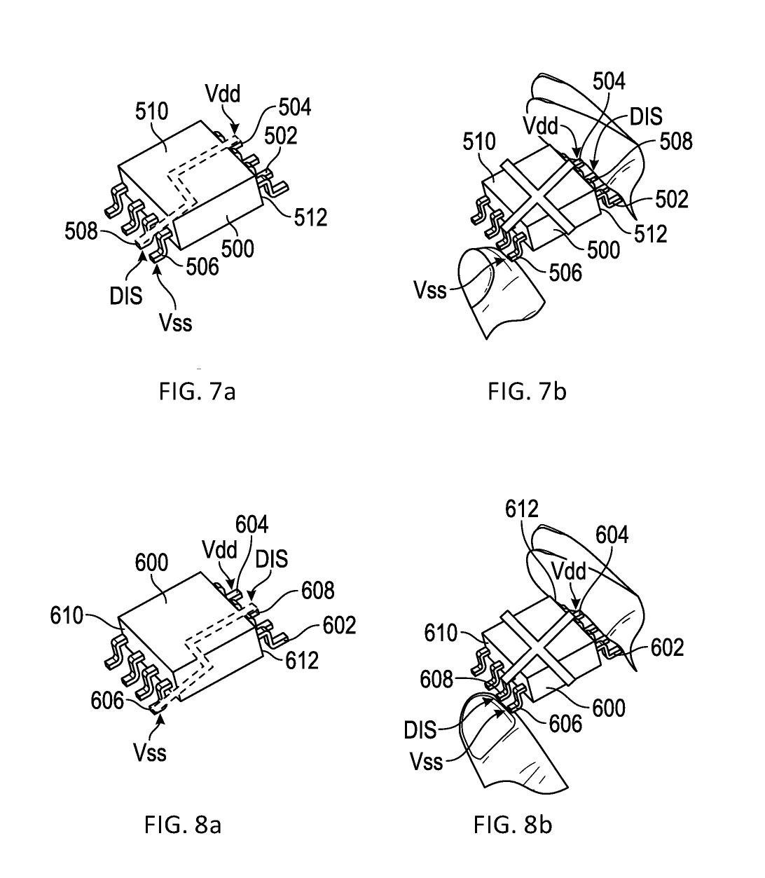

Referring to FIGS. 7a and 7b, an IC package 500 is depicted with a plurality of pins 502. One of the pins, pin 504, is associated with a power rail Vdd of the IC, a second of the pins, pin 506, is associated with a power rail Vss of the IC, and a third of the pins, pin 508, is associated with a disable/enable device of an ESD protection circuit of the IC. The rail Vdd, rail Vss and disable/enable device are internal to the IC package and not visible in FIGS. 8a and 8b, but may be as shown and described in connection with FIGS. 1-6. The disable/enable device of the IC is therefore configured as a high-effective device. As such, the disable/enable pin 508 is preferably positioned adjacent Vss pin 506. Alternatively, the disable/enable pin 508 is positioned at least on a common side 510 of the IC package 500 as Vss pin 506 and opposite a side 512 on which Vdd pin 508 is positioned. In still another arrangement, the disable/enable pin 508 is positioned on the IC package 500 as far from the Vdd pin 504 and as close to the Vss pin 506 as permitted by the package design and layout. Generally, the disable/enable pin 508 is positioned on the IC package and relative to the Vdd pin 504 such that it is unlikely that in handling of the IC package 500 an electrical connection, such as may be made by a human finger, is made between the disable/enable pin 508 and Vdd pin 504. An exemplary arrangement is shown in FIG. 8a. FIG. 8b illustrates the opposite, an arrangement to be avoided, where in handling the IC package a human finger may simultaneously contact the disable/enable pin 508 and the Vdd pin 504.

For an IC in which the disable/enable devices are implemented as low-effective devices, arrangement of pins on the IC package may be as shown in FIG. 8a while avoiding the arrangement of FIG. 8b. Referring to FIGS. 8a and 8b, an IC package 600 is depicted with a plurality of pins 602. One of the pins, pin 604, is associated with a power rail Vdd of the IC, a second of the pins, pin 606, is associated with a power rail Vss of the IC, and a third of the pins, pin 608, is associated with a disable/enable device of an ESD protection circuit of the IC. The rail Vdd, rail Vss and disable/enable device are internal to the IC package and not visible in FIGS. 8a and 8b, but may as shown and described in connection with FIGS. 1-6. The disable/enable device of the IC is therefore configured as a low-effective device. As such, the disable/enable pin 608 is preferably positioned adjacent Vdd pin 604. Alternatively, the disable/enable pin 608 is positioned at least on a common side 612 of the IC package 600 as Vdd pin 604 and opposite a side 610 on which Vss pin 606 is disposed. In still another arrangement, the disable/enable pin 608 is positioned on the IC package 600 as far from the Vss pin 606 and as close to the Vdd pin 604 as possible. Generally, the disable/enable pin 608 is positioned on the IC package and relative to the Vss pin 606 such that it is unlikely that in handling of the IC package an electrical connection, such as may be made by a human finger, is made between the disable/enable pin 608 and Vss pin 606. An exemplary arrangement is shown in FIG. 8a. FIG. 8b illustrates the opposite, an arrangement to be avoided, where in handling the IC package a human finger may simultaneously contact the disable/enable pin 608 and the Vss pin 606.

As herein disclosed and described, embodiments of disable/enable devices are shown that couple to pin outs of the IC package. The pin arrangement is arranged to reduce or eliminate the possibility of inadvertent coupling of the disable/enable pin and either the Vdd or Vss pin, depending on a configuration of the disable/enable devices. Once mounted to a printed circuit board (PCB), the ESD protection circuit is easily disabled by an explicitly wired connection on the PCB as shown in FIG. 8a and FIG. 8a, to ensure that it does not interfere with normal operation of the IC. However, because the ESD protection circuit is responsive to the disable/enable device, ESD protection is automatically enabled by removal of the IC from the PCB or by removal of a signal from the disable/enable pin. In this regard, an advantage is obtained over one-time, fused disabled ESD circuits.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the application in any way. Rather, the foregoing detailed description will provide those skilled in the art with a convenient road map for implementing one or more embodiments, it being understood that various changes may be made in the function and arrangement of elements described in an exemplary embodiment without departing from the scope, as set forth in the appended claims.

What is claimed is:

1. An integrated circuit having electrostatic discharge protection comprising:
a first power rail and a second power rail;
a transistor having a drain operably coupled to the first power rail and a drain operatively couple to the second power rail;
a trigger circuit operatively coupled to the first power rail and the second power rail and to a gate of the transistor, the trigger circuit being operable to turn the transistor on responsive to an ESD event affecting one of the first power rail and the second power rail;
the transistor and trigger circuit together forming an ESD protection circuit for the integrated circuit; and
an ESD protection disable/enable device operatively associated with the ESD protection circuit, the ESD protection disable/enable device being operable to selectively disable the ESD protection circuit.

2. The integrated circuit of claim 1, wherein the ESD protection disable/enable device is coupled to a pin out of a package of the integrated circuit.

3. The integrated circuit of claim 2, wherein the ESD protection circuit is addressable via the pin out to selectively enable and disable the ESD protection circuit.

4. The integrated circuit of claim 1, wherein the ESD protection circuit further comprises a buffer circuit, and the ESD protection disable/enable device is operatively coupled with one of the trigger circuit, the buffer circuit and the transistor.

5. The integrated circuit of claim 1 comprising a plurality of ESD protection circuits, and a ESD protection disable/enable device is associated with each of the plurality of ESD protection circuits.

6. The integrated circuit of claim 5, wherein each of the ESD protection disable/enable devices is addressable via a common IC package pin out.

7. The integrated circuit of claim 1, wherein the ESD protection circuit disable/enable device comprises a switchable transistor.

8. A package for an integrated circuit, the integrated circuit comprising an ESD protection circuit operatively disposed within the integrated circuit and an ESD protection disable/enable device operatively associated with the ESD protection circuit, and wherein the package comprises:
a plurality of pin outs, a first pin out of the plurality being associated with a first power rail;
a second pin out of the plurality of pin outs being associated with a second power rail; and
a third pin out of the plurality of pin outs being associated with the ESD protection disable/enable device.

9. The package of claim 8, wherein the first pin out is disposed on a first side of the package and the second pin out is disposed on a second side of the package,
the ESD protection circuit disable/enable device being a high-effective device,
the first power rail being a positive potential rail, and
the third pin out being located on the first side.

10. The package of claim 9, the third pin out being located adjacent to the first pin out.

11. The package of claim 9, the third pin out being located on the package to maximize a separation of the third pin out from the second pin out.

12. The package of claim 8, wherein the first pin out is disposed on a first side of the package and the second pin out is disposed on a second side of the package;
the ESD protection circuit disable/enable device being a low-effective device;
the first power rail being a ground potential rail; and
the third pin out being located on the first side.

13. The package of claim 12, the third pin out being located adjacent to the first pin out.

14. The package of claim 12, the third pin out being located on the package to maximize a separation of the third pin out from the second pin out.

15. In an integrated circuit, the integrated circuit including an electrostatic discharge (ESD) protection circuit operatively disposed within the integrated circuit, the ESD protection circuit being configured to effectively dissipate an ESD event affecting the integrated circuit, a method of disabling/enabling the ESD protection circuit comprising:
associating an ESD protection disable/enable device with the ESD protection circuit;
coupling the ESD protection disable/enable device to an enable/disable pin out of a package of the integrated circuit; and
addressing the disable/enable device via the disable/enable pin out to disable/enable the ESD protection circuit to selectively enable or disable the ESD protection circuit.

16. The method of claim 15, wherein the ESD protection circuit comprises a trigger circuit, a buffer circuit and a transistor, and wherein the ESD protection disable/enable device is operatively coupled with one of the trigger circuit, the buffer circuit and the clamp transistor.

17. The method of claim 15, wherein the integrated circuit comprises a package, the package having a first pin out associated with a first power rail of the integrated circuit, a second pin out associated with a second power rail of the integrated circuit, the first power rail is a positive potential power rail and the ESD protection disable/enable device is a high effective device, and wherein the disable/enable pin out is positioned on the package adjacent the first pin out.

18. The method of claim 15, wherein the integrated circuit comprises a package, the package having a first pin out associated with a first power rail of the integrated circuit, a second pin out associated with a second power rail of the integrated circuit, the first power rail is a positive potential power rail and the ESD protection disable/enable device is a high effective device, and wherein the disable/enable pin out is positioned on the package on a side of the package opposite a side of the package one which the second pin out is disposed.

19. The method of claim 15, wherein the integrated circuit comprises a package, the package having a first pin out associated with a first power rail of the integrated circuit, a second pin out associated with a second power rail of the integrated circuit, the first power rail is a positive potential power rail and the ESD protection disable/enable device is a low effective device, and wherein the disable/enable pin out is positioned on the package on a side of the package adjacent the second pin out.

20. The method of claim 15, wherein the integrated circuit comprises a package, the package having a first pin out associated with a first power rail of the integrated circuit, a second pin out associated with a second power rail of the integrated circuit, the first power rail is a positive potential power rail and the ESD protection disable/enable device is a low effective device, and the disable/enable pin out is positioned on the package on a side of the package opposite a side of the package one which the first pin out is disposed.
